(19) United States
(12) Patent Application Publication
(10) Pub. No.: US 2026/0324265 A1
(43) Pub. Date: Oct. 15, 2026

(54) DISPLAY PANEL, METHOD FOR MANUFACTURING DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Yue ZHANG, Beijing (CN); Juanjuan YOU, Beijing (CN); Renquan GU, Beijing (CN); Dandan ZHOU, Beijing (CN)

(73) Assignees: Beijing BOE Technology Development Co., Ltd., Beijing (CN); BOE Technology Group Co., Ltd., Beijing (CN)

(21) Appl. No.: 18/838,218

(22) PCT Filed: Dec. 11, 2023
(86) PCT No.: PCT/CN2023/137975

§ 371 Date: Aug. 13, 2024

(51) Int. Cl. H10K 59/80; H10K 59/12; H10K 59/35

(52) U.S. Cl. CPC H10K 59/879; H10K 59/1201; H10K 59/35

(57) ABSTRACT

The disclosure provides a display panel. The display panel includes: a substrate, a light-extraction structure layer, and a plurality of light-emitting units. The light-extraction structure layer includes a plurality of light-extraction structures, wherein the light-extraction structure is provided with a plurality of first recess structures recessed in a direction towards the substrate on a side, away from the substrate, of the light-extraction structure, the first recess structure being provided with one or more first sub-recess structures recessed in the direction towards the substrate on a side, away from the substrate, of the first recess structure. Moreover, the light-emitting unit has a structure with a shape similar to the shape of the light-extraction structure.

### CROSS-REFERENCE TO RELATED APPLICATION

This application is a U.S. national stage of international application No. PCT/CN2023/137975, filed on Dec. 11, 2023, the disclosure of which is herein incorporated by reference in its entirety.

### TECHNICAL FIELD

The present disclosure relates to the field of display technology, and in particular, to a display panel, a method for manufacturing a display panel, and a display device.

### BACKGROUND

Display panels are devices capable of displaying images.

### SUMMARY

Embodiments of the present disclosure provide a display panel, a method for manufacturing a display panel, and a display device. The described technical solutions are as follows.

According to a first aspect of the present disclosure, a display panel is provided. The display panel includes:
a substrate;
a light-extraction structure layer, wherein the light-extraction structure layer includes a plurality of light-extraction structures, each of the plurality of light-extraction structures being disposed on the substrate and provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure; and
a plurality of light-emitting units, wherein the plurality of light-emitting units are disposed on the substrate having the light-extraction structure layer and respectively correspond to the plurality of light-extraction structures, each of the plurality of light-emitting units covers the light-extraction structure corresponding to the light-emitting unit, and the light-emitting unit is provided with a second recess structure corresponding to the first recess structure and a second sub-recess structure corresponding to the first sub-recess structure, wherein the second recess structure has a recessed direction the same as a recessed direction of the first recess structure, an orthographic projection of the second recess structure on the substrate is overlapped with an orthographic projection of the corresponding first recess structure on the substrate, the second sub-recess structure has a recessed direction the same as a recessed direction of the first sub-recess structure, and an orthographic projection of the second sub-recess structure on the substrate is overlapped with an orthographic projection of the corresponding first sub-recess structure on the substrate.

In some embodiments, the plurality of light-emitting units include light-emitting units of at least three colors; wherein
light-emitting units of at least two different colors in the light-emitting units of at least three colors correspond to different target ratios of the first sub-recess structure in the light-extraction structure, each of the target ratios being a ratio of the orthographic projection of the first sub-recess structure on the substrate to an orthographic projection of the light-extraction structure on the substrate.

In some embodiments, in the light-emitting units of at least three colors, the light-emitting units of different colors correspond to the different target ratios of the first sub-recess structure in the light-extraction structure.

In some embodiments, each of the target ratios of the first sub-recess structure in the light-extraction structure is negatively correlated with a lifetime of the light-emitting unit corresponding to the light-extraction structure.

In some embodiments, the first recess structure includes a first bottom and a first sidewall on a side, away from the substrate, of the first bottom, the first sidewall having a slope angle ranging from 30 degrees to 45 degrees.

In some embodiments, the light-emitting unit includes a first portion disposed on the first bottom and a second portion disposed on the first sidewall, the first portion having a thickness greater than a thickness of the second portion.

In some embodiments, the first sub-recess structure includes a second bottom and a second sidewall on a side, away from the substrate, of the second bottom, the second sidewall having a slope angle ranging from 30 degrees to 45 degrees.

In some embodiments, each of the plurality of first recess structures is provided with one first sub-recess structure, a geometric center of the first sub-recess structure being on a centerline of the first recess structure.

In some embodiments, each of the plurality of first recess structures is provided with one first sub-recess structure, a geometric center of the first sub-recess structure being outside a centerline of the first recess structure.

In some embodiments, each of the plurality of first recess structures is provided with two first sub-recess structures of different sizes, the two first sub-recess structures being connected.

In some embodiments, each of the plurality of first recess structures is provided with a plurality of first sub-recess structures, the plurality of first sub-recess structures including a central sub-recess structure and a plurality of peripheral sub-recess structures surrounding the central sub-recess structure.

In some embodiments, each of the plurality of first recess structures is provided with a plurality of first sub-recess structures, the plurality of first sub-recess structures being arranged around a centerline of the first recess structure.

In some embodiments, a plurality of sub-regions are arranged on a side, away from the substrate, of the first recess structure, each of the plurality of sub-regions being a region with a slope angle monotonic in a direction perpendicular to the substrate, and the plurality of sub-regions satisfying:

$${\sum }_{i = 1}^{k} ( {d}_{i} / tan {θ}_{i} ) = D 1 ;$$

wherein k represents a number of the plurality of sub-regions, d represents a dimension of the sub-region in the direction perpendicular to the substrate, θ represents an angle between a line connecting two endpoints on the sub-region and the substrate, the two endpoints being respectively a point in the sub-region furthest from the substrate and a point in the sub-region closest to the substrate, and D1 represents a dimension of the first recess structure in a direction parallel to the substrate.

In some embodiments, the angle θ between the line connecting the two endpoints on the sub-region and the substrate ranges from 30 degrees to 45 degrees.

In some embodiments, the first recess structure and the first sub-recess structure each include a curved recess structure or a trapezoidal recess structure, the trapezoidal recess structure having a trapezoidal section in a direction perpendicular to the substrate.

In some embodiments, the first recess structure has a dimension ranging from 3 microns to 10 microns in a direction parallel to the substrate.

In some embodiments, the first sub-recess structure has a dimension greater than or equal to 2 microns in a direction parallel to the substrate.

According to another aspect of the present disclosure, a method for manufacturing a display panel is provided. The method includes:
acquiring a substrate;
forming a light-extraction structure layer on the substrate, wherein the light-extraction structure layer includes a plurality of light-extraction structures, the plurality of light-extraction structures being disposed on the substrate, and each of the plurality of light-extraction structures being provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure; and
forming a plurality of light-emitting units on the substrate where the plurality of light-extraction structures are formed, wherein the plurality of light-emitting units respectively correspond to the plurality of light-extraction structures, each of the plurality of light-emitting units covers the light-extraction structure corresponding to the light-emitting unit, the light-emitting unit is configured to emit light beams in a direction towards the substrate, and the light-emitting unit is provided with a second recess structure corresponding to the first recess structure and a second sub-recess structure corresponding to the first sub-recess structure, wherein the second recess structure has a recessed direction the same as a recessed direction of the first recess structure, an orthographic projection of the second recess structure on the substrate is overlapped with an orthographic projection of the first recess structure on the substrate, the second sub-recess structure has a recessed direction the same as a recessed direction of the first sub-recess structure, and an orthographic projection of the second sub-recess structure on the substrate is overlapped with an orthographic projection of the first sub-recess structure on the substrate.

In some embodiments, forming the light-extraction structure layer on the substrate includes:
forming a light-extraction structure material layer on the substrate;
forming the plurality of first recess structures recessed in the direction towards the substrate on a side, away from the substrate, of the light-extraction structure material layer by an exposure and developing process;
forming the one or more first sub-recess structures recessed in the direction towards the substrate by a light curing process; and
forming the light-extraction structure layer by a baking process.

According to another aspect of the present disclosure, a display device is provided. The display device includes a power assembly and a display panel as defined in any one of the above aspects.

### BRIEF DESCRIPTION OF DRAWINGS

For clearer descriptions of the technical solutions according to the embodiments of the present disclosure, the following briefly describes the accompanying drawings required for describing the embodiments. Apparently, the accompanying drawings in the following description show merely some embodiments of the present disclosure, and a person skilled in the art may still derive other drawings from these accompanying drawings without creative efforts.

FIG. 1 is a top view of a display panel according to some embodiments of the present disclosure;

FIG. 2 is a schematic cross-sectional structural diagram of the display panel in FIG. 1;

FIG. 3 is an enlarged structural diagram of the display panel in FIG. 1;

FIG. 4 is a schematic cross-sectional structural diagram of another display panel according to some embodiments of the present disclosure;

FIG. 5 is a schematic cross-sectional structural diagram of another display panel according to some embodiments of the present disclosure;

FIG. 6 is a top view of the display panel in FIG. 5;

FIG. 7 is a schematic cross-sectional structural diagram of another display panel according to some embodiments of the present disclosure;

FIG. 8 is a top view of the display panel in FIG. 7;

FIG. 9 is a schematic cross-sectional structural diagram of a portion of another display panel according to some embodiments of the present disclosure;

FIG. 10 is a schematic cross-sectional structural diagram of a light-extraction structure according to the related art:

FIG. 11 is a schematic cross-sectional structural diagram of a portion of another display panel according to some embodiments of the present disclosure;

FIG. 12 is a schematic cross-sectional structural diagram of another light-extraction structure according to some embodiments of the present disclosure;

FIG. 13 is a schematic cross-sectional structural diagram of another light-extraction structure according to some embodiments of the present disclosure;

FIG. 14 is a schematic cross-sectional structural diagram of another light-extraction structure according to some embodiments of the present disclosure;

FIG. 15 is a schematic cross-sectional structural diagram of another light-extraction structure according to some embodiments of the present disclosure;

FIG. 16 is a schematic cross-sectional structural diagram of another light-extraction structure according to some embodiments of the present disclosure;

FIG. 17 is a schematic cross-sectional structural diagram of a portion of another display panel according to some embodiments of the present disclosure;

FIG. 18 is a schematic cross-sectional structural diagram of another display panel according to some embodiments of the present disclosure;

FIG. 19 is a flowchart of a method for manufacturing a display panel according to some embodiments of the present disclosure;

FIG. 20 is a flowchart of another method for manufacturing a display panel according to some embodiments of the present disclosure;

FIG. 21 is a schematic diagram of a process for preparing a first sub-recess structure according to some embodiments of the present disclosure;

FIG. 22 is a flowchart of another method for manufacturing a display panel according to some embodiments of the present disclosure;

FIG. 23 is a schematic diagram of a process for preparing another first sub-recess structure according to some embodiments of the present disclosure;

FIG. 24 is a schematic cross-sectional structural diagram of a hard mask according to some embodiments of the present disclosure; and

FIG. 25 is a schematic cross-sectional structural diagram of a hard mask according to some embodiments of the present disclosure.

Some specific embodiments of the present disclosure are shown by means of the above-described accompanying drawings, which are described in detail hereinafter. These accompanying drawings and textual descriptions are not intended to limit, in any way, the scope of the conception of the present disclosure, but rather to illustrate the concepts of the present disclosure for those skilled in the art by reference to particular embodiments.

### DETAILED DESCRIPTION

In order to make the purpose, technical solutions, and advantages of the present disclosure clearer, the following further describes the embodiments of the present disclosure in detail in conjunction with the accompanying drawings.

A display panel typically includes a substrate and a light-emitting unit disposed on the substrate. The display panel is a bottom-emitting display panel, wherein the light-emitting unit is configured to emit light beams in a direction towards the substrate, thereby enabling the display panel to achieve the display function.

However, the display panel has a smaller light-emitting area, resulting in lower brightness of the display panel.

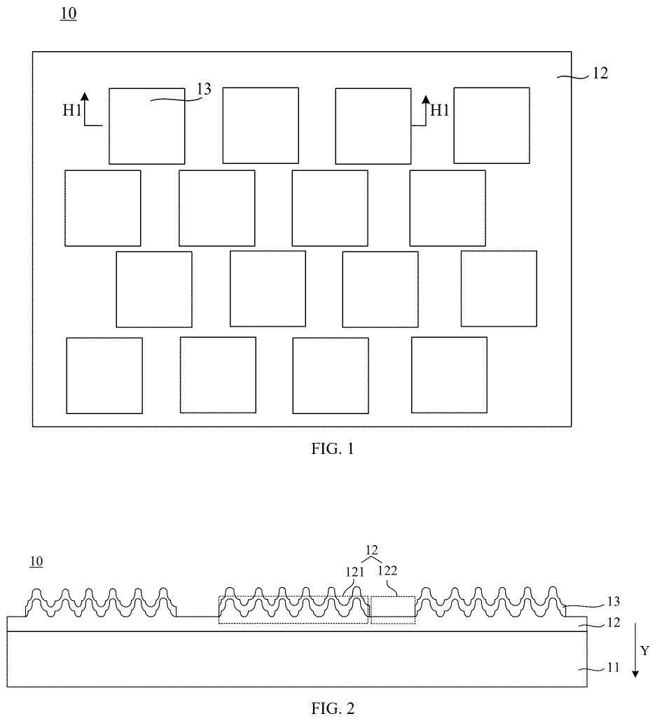

Embodiments of the present disclosure provide a display panel. Referring to FIGS. 1, 2, and 3, FIG. 1 being a top view of a display panel according to the embodiments of the present disclosure, FIG. 2 being a schematic cross-sectional structural diagram of the display panel in FIG. 1 (FIG. 2 is a schematic diagram of a cross-sectional structure at H1-H1 of the display panel in FIG. 1), and FIG. 3 being an enlarged structural diagram of the display panel in FIG. 1 (FIG. 3 is an enlarged structural diagram of a region corresponding to a light-emitting unit in the display panel in FIG. 1), the display panel 10 includes:
a substrate 11;
a light-extraction structure layer 12, wherein the light-extraction structure layer 12 includes a plurality of light-extraction structures 121, the plurality of light-extraction structures 121 being disposed on the substrate 11, and each of the plurality of light-extraction structures 121 being provided with a plurality of first recess structures A1 recessed in a direction Y towards the substrate 11 on a side, away from the substrate 11, of the light-extraction structures 121, wherein each of the plurality of first recess structures A1 is provided with one or more first sub-recess structures B1 recessed in the direction towards the substrate on a side, away from the substrate, of the first recess structure A1; and
a plurality of light-emitting units 13, wherein the plurality of light-emitting units 13 are disposed on the substrate having the light-extraction structure layer 12, the plurality of light-emitting units 13 respectively correspond to the plurality of light-extraction structures 121, each of the plurality of light-emitting units 13 covers the light-extraction structure 121 corresponding to the light-emitting unit 13, and the light-emitting unit 13 is provided with a second recess structure A2 corresponding to the first recess structure A1 and a second sub-recess structure B2 corresponding to the first sub-recess structure B1, wherein the second recess structure A2 has a recessed direction the same as a recessed direction of the first recess structure A1, an orthographic projection of the second recess structure A2 on the substrate 11 is overlapped with an orthographic projection of the corresponding first recess structure A1 on the substrate 11, the second sub-recess structure B2 has a recessed direction the same as a recessed direction of the first sub-recess structure B1, and an orthographic projection of the second sub-recess structure B2 on the substrate 11 is overlapped with an orthographic projection of the corresponding first sub-recess structure A1 on the substrate 11. Because the materials of the various film layers in the light-emitting unit 13 are flexible, a structure having a similar shape to the light-extraction structure 121 is formed on the light-emitting unit 13 in some embodiments.

It should be noted that FIGS. 2 and 3 illustrate a case in which the first recess structure A1 is provided with one first sub-recess structure B1 recessed in the direction towards the substrate on the side, away from the substrate, of the first recess structure A1, but there are other cases for the display panels provided by embodiments of the present disclosure, such as a case in which the first sub-recess structure A1 is provided with two, three, or four first sub-recess structures B1 recessed in the direction towards the substrate on the side, away from the substrate, of the first recess structure A1.

In summary, a display panel including a substrate, a light-extraction structure layer, and a plurality of light-emitting units is provided. The light-extraction structure layer includes a plurality of light-extraction structures, wherein each of the plurality of light-extraction structures is provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure. Moreover, the light-emitting unit has a structure with a shape similar to the shape of the light-extraction structure. In this way, the light-emitting area of the light-emitting unit can be increased, and thus the brightness of the display panel can be enhanced.

In some embodiments of the present disclosure, the display panel is an Organic Light Emitting Diode (OLED) display panel. Referring to FIGS. 1, 2, and 3, in some embodiments, the light-emitting unit 13 is configured to emit light beams in a direction towards the substrate 11, i.e., the light-emitting mode of the display panel 10 according to the embodiments of the present disclosure is a bottom-emission type. Due to the larger pixel area of the large-sized display panel, there is sufficient space for setting the thin film transistors and the wire lines, the influence of the thin film transistors and the wire lines on the brightness of the display panel is reduced, and thus the bottom-emission type light-emitting mode can be applied to the large-sized high-resolution OLED display panel.

In some embodiments, the substrate 11 is configured to carry other film layers in the display panel 10 to improve the flatness of the other film layers. In some embodiment, the light-emitting mode of the display panel 10 provided by the embodiments of the present disclosure is the bottom-emission type, and correspondingly, the substrate 11 is a light-transmitting substrate, and the light-emitting unit 13 is configured to emit light beams in the direction Y towards the substrate 11. In some embodiments, the material of the substrate 11 includes a variety of light-transmitting materials such as glass.

The light-extraction structure layer 12 includes a light-extraction structure 121 corresponding to the light-emitting unit 13, and in a region other than the light-extraction structure 121, the light-extraction structure layer 12 includes a planarization structure 122. In some embodiments, a surface of a side, away from the substrate 13, of the planarization structure 122 is parallel to the substrate 11, and the planarization structure 122 achieves a function of planarization. In some embodiments, the material of the light-extraction structure layer 12 includes a resin material.

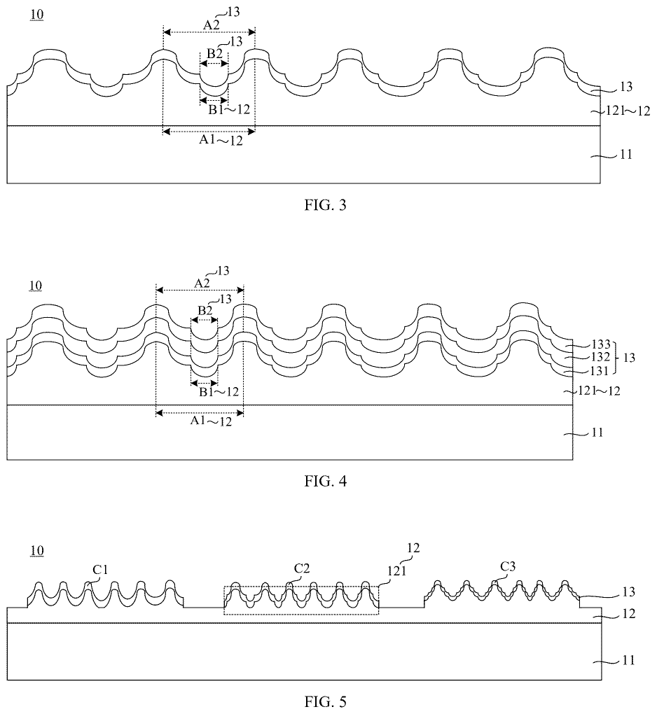

In some embodiments, the light-emitting unit 13 is configured to emit light beams in a direction towards the substrate 11 to enable the display panel 10 to achieve a display function. In some embodiments, referring to FIG. 4, FIG. 4 being a schematic cross-sectional structural diagram of another display panel according to some embodiments of the present disclosure, the light-emitting unit 13 includes a first electrode 131, a light-emitting layer 132, and a second electrode 133, wherein the first electrode 131 in cooperation with the second electrode 133 drives the light-emitting layer 132 to emit light. In some embodiments, the first electrode 131 is an anode, and illustratively, the material of the first electrode 131 includes indium tin oxide (ITO). In some embodiments, the second electrode 133 is a cathode, and the light-emitting layer 132 is an organic electroluminescent layer. In some embodiments, the first electrode 131, the light-emitting layer 132, and the second electrode 133 all have recess structures with shapes similar to the shape of the light-extraction structure 121, thereby causing the light-emitting unit 13 to have a second recess structure A2 corresponding to the first recess structure A1 and a second sub-recess structure B2 corresponding to the first sub-recess structure B1, which in turn increases the light-emitting area of the light-emitting layer 132, and then increases the brightness of the display panel 10. Illustratively, the manufacturing processes of the first electrode 131, the light-emitting layer 132, and the second electrode 133 include evaporation processes.

In addition, because the first recess structure A1 and the first sub-recess structure B1 of the light-extraction structure 121 have inclined sidewalls, the thicknesses of the first electrode 131, the light-emitting layer 132, and the second electrode 133, at the sidewall position, formed on the side, away from the substrate 11, of the light-extraction structure 121 can be reduced. In the case that the light-emitting layer 132 is thinner, the holes provided by the first electrode 131 and the electrons provided by the second electrode 133 pass through a shorter distance, and the electrons and holes are more likely to meet and recombine to emit light at the light-emitting layer 132, such that the main light-emitting region of the light-emitting layer 132 is concentrated to the positions where the film layer is thinner, i.e., the current is easy to flow to the light-emitting layer 132 at the sidewall position. Therefore, the light-emitting area of the display panel can be increased and the current density of the display panel can be reduced, then the decay rate of the display panel can be reduced, and thus the lifetime of the display panel can be improved.

In addition, in the light emitted by the light-emitting unit 13 of the display panel 10, the light having an emergence angle greater than the critical angle of total reflection between the substrate 11 and the air is reflected into the display panel 10 and cannot be emitted out. In some embodiments, the refractive index of the light-extraction structure layer 12 is less than the refractive index of the first electrode 131, such that the light emitted by the light-emitting layer 132 is reflected during the process of passing through the first recess structure A1 and the first sub-recess structure B1, and thus the travel path of the light is changed. In some embodiments, the refractive index of the light-extraction structure layer 12 is in the range of 1.5 to 1.6, illustratively, the refractive index of the light-extraction structure layer 12 is 1.5. Upon the light being reflected multiple times by the light-extraction structure layer 12, it is possible to make the angle of incidence of the light at the interface between the substrate 11 and the air less than the critical angle of total reflection between the substrate 11 and the air, i.e., the light is not totally reflected at the interface between the substrate 11 and the air. Therefore, the light-extraction structure 121 can reduce the amount of light that is confined within the display panel 10, and thus can improve the light extraction efficiency of the display panel 10.

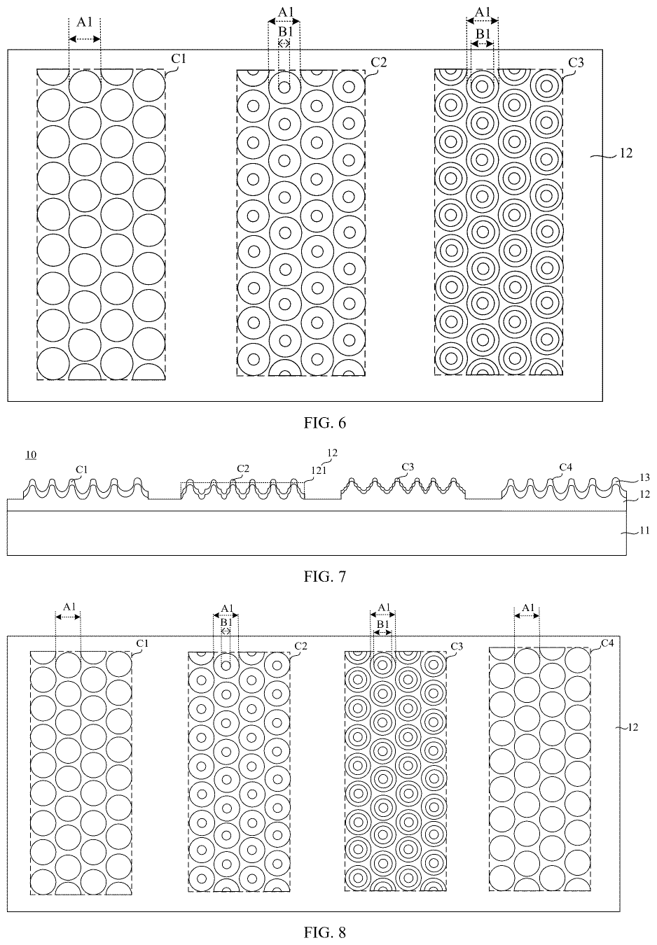

In some exemplary embodiments, the plurality of light-emitting units includes light-emitting units of at least three colors. In some embodiments, the plurality of light-emitting units include light-emitting units of three colors. Referring to FIGS. 5 and 6, FIG. 5 being a schematic cross-sectional structural diagram of another display panel according to the embodiments of the present disclosure, and FIG. 6 being a top-view of the display panel in FIG. 5 (in order to clearly illustrate the light-extraction structure, FIG. 6 does not show the specific light-emitting unit), the display panel 10 includes: a substrate 11, a light-extraction structure layer 12, and a plurality of light-emitting units 13, wherein the plurality of light-emitting units 13 includes light-emitting units of three colors: a first light-emitting unit C1, a second light-emitting unit C2, and a third light-emitting unit C3. In some embodiments, the first light-emitting unit C1 is a red light-emitting unit, the second light-emitting unit C2 is a green light-emitting unit, and the third light-emitting unit C3 is a blue light-emitting unit. In addition, the shapes, from a top view, of the first recess structure A1 and the first sub-recess structure B1 shown in FIG. 6 are circular, but the shapes, from a top view, of the first recess structure A1 and the first sub-recess structure B1 are also possible to be elliptical or polygonal, which are not limited in the embodiments of the present disclosure.

In some embodiments, in the light-emitting units of at least three colors, light-emitting units of at least two different colors correspond to different target ratios of the first sub-recess structure in the light-extraction structure, each of the target ratios being a ratio of the orthographic projection of the first sub-recess structure on the substrate to the orthographic projection of the light-extraction structure on the substrate. In some embodiments, among the light-emitting units of at least three colors, there is a case that the light-emitting units of any two different colors correspond to different target ratios of the first sub-recess structure in the light-extraction structure. In some embodiments of the present disclosure, there is a case that the light-emitting units of more than two different colors correspond to different target ratios of the first sub-recess structure in the light-extraction structure. Because the lifetimes of the light-emitting materials of different colors are different, the lifetimes of the light-emitting units of different colors are also different. Increasing the target ratio of the first sub-recess structure can increase the light-emitting area of the corresponding light-emitting unit. Based on the above, the target ratio of the first sub-recess structure is adjusted in the embodiments of the present disclosure according to the lifetimes of the light-emitting units of different colors, so as to enhance the uniformity of the lifetimes of the light-emitting units of different colors in the display panel.

In some embodiments, the light-emitting units of different colors correspond to different target ratios of the first sub-recess structures in the light-extraction structures. Illustratively, in the light-emitting units 13 of three colors illustrated in FIG. 6, the first light-emitting unit C1 corresponds to a target ratio of the first sub-recess structure B1 in the light-extraction structure 121 as W1, the second light-emitting unit C2 corresponds to a target ratio of the first sub-recess structure B1 in the light-extraction structure 121 as W2, and the third light-emitting unit C3 corresponds to a target ratio of the first sub-recess structure B1 in the light-extraction structure 121 as W3, the values of W1, W2, and W3 being different.

In some embodiments, each of the target ratios of the first sub-recess structure B1 in the light-extraction structure 121 is negatively correlated with the lifetime of the light-emitting unit 13 corresponding to the light-extraction structure 121, i.e., the longer the lifetime of the light-emitting unit 13 corresponding to the light-extraction structure 121 is, the smaller the target ratio of the first sub-recess structure B1 in the light-extraction structure 121 is; and the shorter the lifetime of the light-emitting unit 13 corresponding to the light-extraction structure 121 is, the larger the target ratio of the first sub-recess structure B1 in the light-extraction structure 121 is. Illustratively, among the light-emitting units 13 of multiple colors, because the lifetime of the first light-emitting unit C1>the lifetime of the second light-emitting unit C2>the lifetime of the third light-emitting unit C3, the target ratios of the first sub-recess structures B1 in the light-extraction structures 121 respectively corresponding to the light-emitting units 13 of multiple colors satisfy: W1<W2<W3, such that the uniformity of lifetimes of the light-emitting units 13 of different colors in the display panel 10 can be improved. Because the light-emitting unit 13 with a shorter lifetime is prone to color deviation and low light-emitting efficiency in the process of use, the problem of color deviation and inconsistent light-emitting efficiencies of the light-emitting units 13 of a plurality of colors due to the inconsistency of the lifetimes of the light-emitting units 13 is avoided and the display effect of the display panel 10 is improved.

In some embodiments, the target ratio is related to the size as well as the number of the first sub-recess structures B1. Illustratively, for the case in which the shapes, from the top views, of the first recess structure A1 and the first sub-recess structure B1 illustrated in FIG. 6 have circular shapes, the target ratios of the first sub-recess structures B1 in the light-extraction structures 121 corresponding to the light-emitting units 13 of the multiple colors are determined based on the diameters of the first sub-recess structures B1. The larger the diameter of the first sub-recess structure B1 is, the larger the size of the first sub-recess structure B1 is, and then the larger the target ratio is, i.e., W1<W2<W3.

The above is the case where the plurality of light-emitting units include light-emitting units of three colors, but the plurality of light-emitting units according to the embodiments of the present disclosure are also possible to include light-emitting units of more than three colors. Illustratively, the plurality of light-emitting units include light-emitting units of four colors: red light-emitting units, green light-emitting units, blue light-emitting units, and white light-emitting units. Among the above units, the white light-emitting unit can enhance the brightness of the display panel, which can improve the display effect of the display panel. In the case where the plurality of light-emitting units include light-emitting units of greater than three colors, it is also possible to satisfy that the light-emitting units of different colors correspond to different target ratios of the first sub-recess structures in the light-extraction structures, so as to improve the uniformity of the lifetimes of the light-emitting units of different colors in the display panel.

Also, in some embodiments, in the case that the lifetimes of the light-emitting units of different colors are close, the target ratios of the first sub-recess structures in the light-extraction structures corresponding to the light-emitting units are the same. Referring to FIGS. 7 and 8, FIG. 7 being a schematic cross-sectional structural diagram of another display panel according to the embodiments of the present disclosure, and FIG. 8 being a top-view of the display panel in FIG. 7 (specific light-emitting unit is not shown in FIG. 8 for the purpose of clearly illustrating the light-extraction structure), the display panel 10 includes: a substrate 11, a light-extraction structure layer 12, and a plurality of light-emitting units 13, wherein the plurality of light-emitting units 13 include light-emitting units of four colors: a first light-emitting unit C1, a second light-emitting unit C2, a third light-emitting unit C3, and a fourth light-emitting unit C4. The lifetime of the first light-emitting unit C1 is close to the lifetime of the fourth light-emitting unit C4, and then the target ratio W1 of the first sub-recess structure B1 in the light-extraction structure 121 corresponding to the first light-emitting unit C1 is equal to the target ratio W4 of the first sub-recess structure B1 in the light-extraction structure 121 corresponding to the fourth light-emitting unit C4, such that the uniformity of the lifetimes of the light-emitting units 13 of the different colors in the display panel 10 can be improved. Therefore, considering that the light-emitting units 13 with shorter lifetimes are prone to color deviation and low light-emitting efficiencies during use, the problem of color deviation and inconsistent light-emitting efficiencies of the light-emitting units 13 of multiple colors due to inconsistent lifetimes is avoided, and the display effect of the display panel 10 is improved.

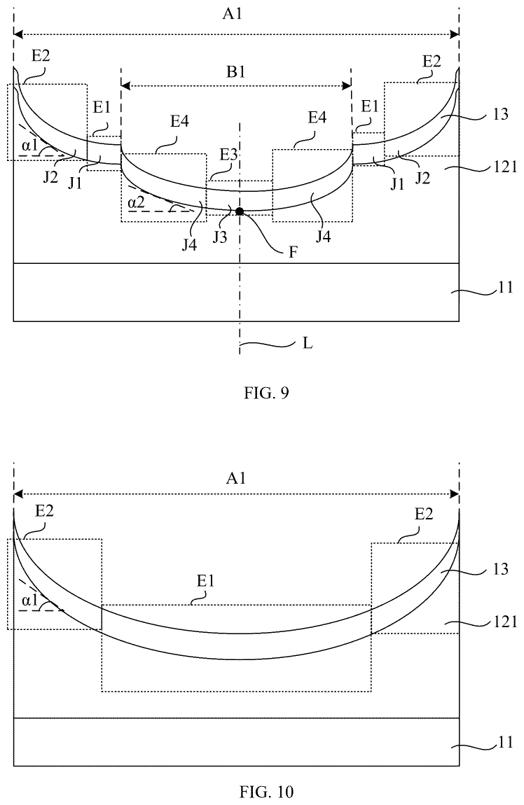

In some embodiments of the present disclosure, the light-extraction structure includes a variety of structures, wherein the shapes of the first recess structure and the first sub-recess structure have a variety of cases. Illustratively, the first recess structure and the first sub-recess structure include curved recess structures. Referring to FIG. 9, which is a schematic cross-sectional structural diagram of a portion of another display panel according to the embodiments of the present disclosure, the first recess structure A1 includes a first bottom E1 and a first sidewall E2 disposed on the side, away from the substrate, of the first bottom E1, wherein a slope angle α1 of the first sidewall E2 ranges from 30 degrees to 45 degrees. The first sub-recess structure B1 includes a second bottom E3 and a second sidewall E4 disposed on the side, away from the substrate, of the second bottom E3, wherein a slope angle α2 of the second sidewall E4 ranges from 30 degrees to 45 degrees. For the curved recess structure as shown in FIG. 9, the slope angle is an angle between a cut surface of the curved surface and an upper surface of the substrate, the values of the slope angles at various positions in the curved recess structure are variable, and the slope angles at various positions on the first sidewall E2 is in the range of 30 degrees to 45 degrees.

Because the film layer in the light-emitting unit 13 can be formed by an evaporation process, the thickness of the film layer in the light-emitting unit 13 at the position of the sidewall is smaller. In some embodiments, the thicknesses of the film layer of the light-emitting unit 13 at the position of the first sidewall E3 and at the position of the second sidewall E4 are reduced by defining the slope angle α1 of the first sidewall E2 and the slope angle α2 of the second sidewall E4 to be greater than 30 degrees. In some embodiments, the film layer of the light-emitting unit 13 includes a light-emitting layer, and the main light-emitting region of the light-emitting layer is concentrated to the position of the film layer where the film layer is thinner, i.e., the current is easy to flow to the light-emitting layer at the position of the first sidewall E3 and at the position of the second sidewall E4, such that the light-emitting area of the display panel can be increased, thereby reducing the current density of the display panel for achieving the desired brightness, then reducing the rate of decay of the brightness of the display panel, and thus increasing the lifetime of the display panel. In addition to the above, by defining the slope angle α1 of the first sidewall E3 and the slope angle α2 of the second sidewall E4 to be less than 45 degrees, the problem of the slope angle α1 and the slope angle α2 being too large leading to breakage or discontinuity of the film layer of the light-emitting unit 13 when forming the film layer is avoided.

In some embodiments, the light-emitting unit 13 includes a first portion J1 disposed on the first bottom E1 and a second portion J2 disposed on the first sidewall E2, the thickness of the first portion J1 being greater than the thickness of the second portion J2. The thickness of the first portion J1 and the thickness of the second portion J2 are respectively the thicknesses of the light-emitting unit 13 of the corresponding portions in a direction perpendicular to the contact surface. In addition, in some embodiments, the light-emitting unit 13 further includes a third portion J3 disposed on the second bottom E3 and a fourth portion J4 disposed on the second sidewall E4, the thickness of the third portion J3 being greater than the thickness of the fourth portion J4. Because the film layer in the light-emitting unit 13 can be formed by an evaporation process, the thicknesses of the second portion J2 on the first sidewall E2 and the fourth portion J4 on the second sidewall E4 are smaller. Because the current flows easily to the position where the film layer is thinner, i.e., the current flows easily to the second portion J2 on the first sidewall E2 and to the fourth portion J4 on the second sidewall E4, the main light-emitting region of the light-emitting unit 13 is concentrated to the second portion J2 on the first sidewall E2 and the fourth portion J4 on the second sidewall E4.

Further, please refer to FIG. 10, which is a schematic cross-sectional structural diagram of a light-extraction structure provided by the related art, the light-extraction structure 121 includes only a first recess structure A1. Compared with the light-extraction structure illustrated in FIG. 10, the first sub-recess structure B1 illustrated in FIG. 9 occupies a region of the first bottom E1 in the first recess structure A1, and thus the area proportion of the sidewalls in the light-extraction structure 121 is increased. In some embodiments, the film layer of the light-emitting unit 13 at the sidewall is thinner and is used as the main light-emitting region, and thus the effective light-emitting area of the display panel is increased.

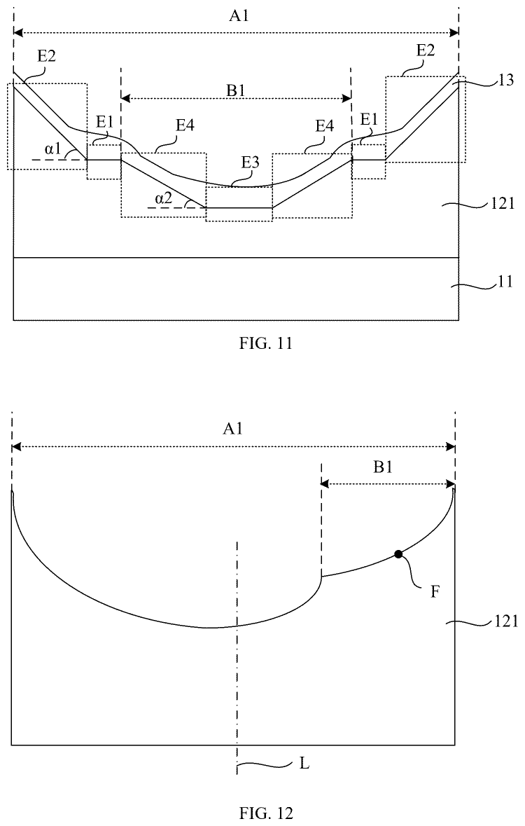

The above is a case in which the first recess structure and the first sub-recess structure include a curved recess structure. In some embodiments, the first recess structure and the first sub-recess structure further include trapezoidal recess structures, which have trapezoidal sections in a direction perpendicular to the substrate. Referring to FIG. 11, which is a schematic cross-sectional structural diagram of a portion of another display panel according to the embodiments of the present disclosure, the first recess structure A1 includes a first bottom E1 and a first sidewall E2 disposed on the side, away from the substrate, of the first bottom E1, wherein a slope angle α1 of the first sidewall E2 is in the range of 30 degrees to 45 degrees. The first sub-recess structure B1 includes a second bottom E3 and a second sidewall E4 disposed on the side, away from the substrate, of the second bottom E3, wherein the slope angle α2 of the second sidewall E4 ranges from 30 degrees to 45 degrees. For the trapezoidal recess structure as shown in FIG. 11, the slope angle is an angle between a surface on which the sidewall is disposed and an upper surface of the substrate, and the value of the slope angle at various positions on the first sidewall E2 is the same in the trapezoidal recess structure. The trapezoidal recess structure can also increase the effective light-emitting area of the display panel, and by defining ranges of the slope angle α1 of the first sidewall E2 and the slope angle α2 of the second sidewall E4, the light-emitting area of the display panel is increased and a current density of the display panel is reduced, which in turn enhance the lifetime of the display panel.

In the embodiments of the present disclosure, the light-extraction structure includes a variety of structures, wherein there are also a variety of numbers of the first sub-recess structures, as well as a variety of positions for disposing the first sub-recess structure on a side, away from the substrate, of the first recess structure. Illustratively, referring to FIG. 9, each of the plurality of first recess structures A1 is provided with one first sub-recess structure B1, a geometric center F of the first sub-recess structure B1 being on a centerline L of the first recess structure A1. In addition to the case illustrated in FIG. 9, in some embodiments, the first sub-recess structure B1 intersects the centerline L of the first recess structure A1, which is not limited in the embodiments of the present disclosure.

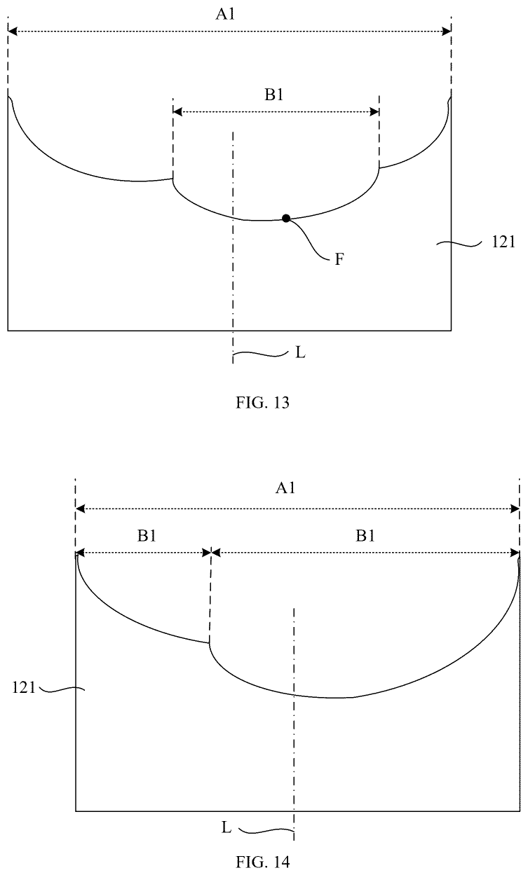

In some embodiments, referring to FIG. 12, FIG. 12 being a schematic cross-sectional structural diagram of another light-extraction structure according to the embodiments of the present disclosure, the first recess structure A1 is provided with one first sub-recess structure B1, a geometric center F of the first sub-recess structure B1 being outside of the centerline L of the first recess structure A1. In addition, FIG. 11 illustrates a case in which the first sub-recess structure B1 as a whole is disposed outside the centerline L. There is also another case for the light-extraction structure according to the embodiments of the present disclosure. Referring to FIG. 13, which is a schematic cross-sectional structural diagram of another light-extraction structure according to the embodiments of the present disclosure, in some embodiments, the first sub-recess structure B1 intersects the centerline L of the first recess structure A1 and the geometrical center F of the first sub-recess structure B1 is outside the centerline L of the first recess structure A1. By making the geometric center F of the first sub-recess structure B1 outside the center line L of the first recess structure A1, it is possible to make the structure of the first recess structure A1 on both sides of the center line L asymmetric, such that scattering of light emitted by the light-emitting unit can be reduced, and thereby avoiding the problem of rainbow patterns appearing on the display panel.

In some embodiments, referring to FIG. 14, FIG. 14 being a schematic cross-sectional structural diagram of another light-extraction structure according to the embodiments of the present disclosure, the first recess structure A1 is provided with two first sub-recess structures B1 of different sizes, wherein the two first sub-recess structures B1 are connected. In the light-extraction structure 121 illustrated in FIG. 14, the structure of the first recess structure A1 on both sides of the centerline L is asymmetric, such that the problem of rainbow patterns appearing on the display panel is also avoided.

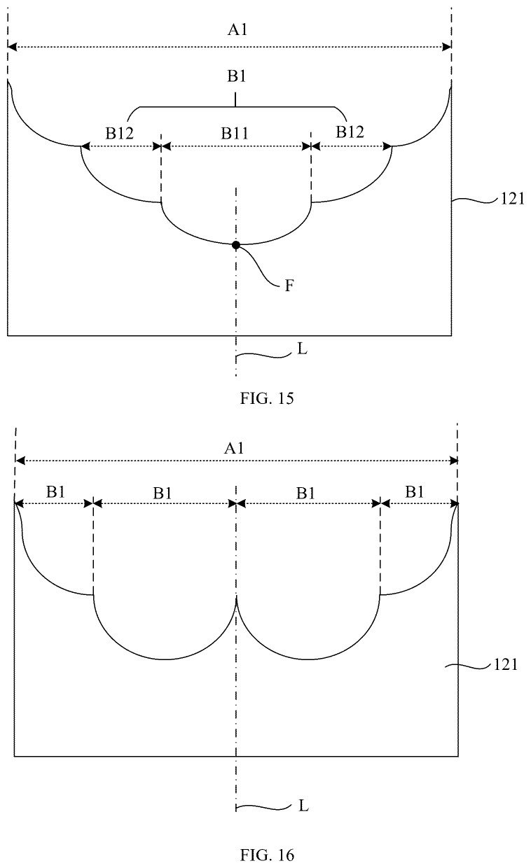

In some embodiments, please refer to FIG. 15, which is a schematic cross-sectional structural diagram of another light-extraction structure according to some embodiments of the present disclosure, the first recess structure A1 is provided with a plurality of first sub-recess structures B1, the plurality of first sub-recess structures B1 including a central sub-recess structure B11 and a plurality of peripheral sub-recess structures B12 surrounding the central sub-recess structure B11. In addition, FIG. 12 illustrates a case where the central sub-recess structure B11 has a geometric center F on the centerline L of the first recess structure A1, but the geometric center F of the central sub-recess structure B11 according to the embodiments of the present disclosure is outside the centerline L of the first recess structure A1 in some embodiments, which is not limited in the embodiments of the present disclosure.

In some embodiments, referring to FIG. 16, FIG. 16 being a schematic cross-sectional structural diagram of another light-extraction structure according to the embodiments of the present disclosure, the first recess structure A1 is provided with a plurality of first sub-recess structures B1, wherein the plurality of first sub-recess structures B1 are arranged around a centerline L of the first recess structure A1. In addition, FIG. 16 illustrates a case in which four first sub-recess structures B1 are arranged around the centerline L of the first recess structure A1, but there are other cases for the number of the first sub-recess structures B1 in the embodiments of present disclosure, such as two, three, or five first sub-recess structures B1 arranged around the centerline L of the first recess structure A1, which is not limited in the embodiments of the present disclosure.

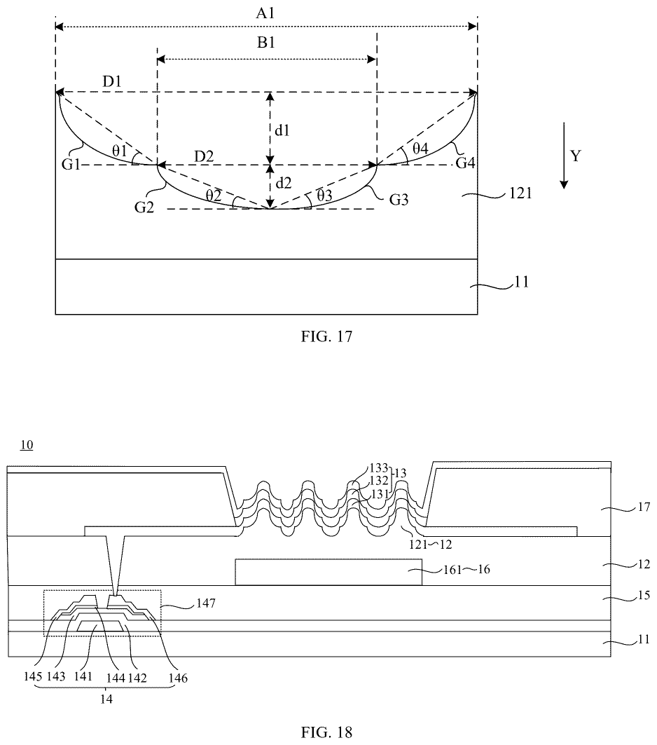

In some embodiments, referring to FIG. 17, which is a schematic cross-sectional structural diagram of a portion of another display panel according to the embodiments of the present disclosure, the first recess structure A1 is provided with a plurality of sub-regions on a side, away from the substrate 11, of the first recess structure, wherein the plurality of sub-regions include a first sub-region G1, a second sub-region G2, a third sub-region G3, and a fourth sub-region G4, wherein each of the plurality of sub-regions is a region with a slope angle monotonic in a direction perpendicular to the substrate 11, and the plurality of sub-regions satisfies:

$${\sum }_{i = 1}^{k} ( {d}_{i} / tan {θ}_{i} ) = D 1 ;$$

wherein k represents a number of the plurality of sub-regions, d represents a dimension of the sub-region in the direction Y perpendicular to the substrate 11, θ represents an angle between a line connecting two endpoints on the sub-region and the substrate, the two endpoints being respectively a point in the sub-region furthest from the substrate 11 and a point in the sub-region closest to the substrate 11, D1 represents a dimension of the first recess structure A1 in a direction parallel to the substrate 11, i represents the i^{th} sub-region in the plurality of sub-regions, dᵢ represents the dimension of the i^{th} sub-region in the direction Y perpendicular to the substrate 11, and θᵢ represents an angle between the line connecting two endpoints on the i^{th} sub-region and the substrate. In some embodiments, based on the above formula, a relationship between the first recess structure A1 and the first sub-recess structure B1 is determined, i.e., the larger the dimension D1 of the first recess structure A1 in the direction parallel to the substrate 11 is, the larger the dimension d of the sub-region in the direction perpendicular to the substrate 11 is, and thus the larger the dimension D2 of the first sub-recess structure B1 in the direction parallel to the substrate 11 is.

In some embodiments, the angle θ between the line connecting the two endpoints on the sub-region and the substrate ranges from 30 degrees to 45 degrees. By defining the angle θ to be in this range, the range of the slope angle of the sub-region is made to be approximate to: 30 degrees to 45 degrees, such that the light-emitting area of the display panel is increased and the current density of the display panel is reduced, which in turn increases the lifetime of the display panel.

In some embodiments, the size D1 of the first recess structure A1 in the direction parallel to the substrate 11 ranges from 3 micrometers to 10 micrometers. By making the dimension D1 of the first recess structure A1 within this range, the first sub-recess structure B1 is made easy to prepare. In addition, in some embodiments, the dimension D1 of the first recess structure A1 in the direction parallel to the substrate 11 is related to the number of the first sub-recess structures B1 in the first recess structure A1, and the fewer the number of the first sub-recess structures B1 in the first recess structure A1 is, the smaller the dimension D1 of the first recess structure A1 in the direction parallel to the substrate 11 is. Illustratively, because the number of the first sub-recess structures B1 in the first recess structure A1 illustrated in FIG. 9 is smaller than the number of the first sub-recess structures B1 in the first recess structure A1 illustrated in FIGS. 14 to 16, the dimension of the first recess structure A1 in the light-extraction structure 121 illustrated in FIG. 9 is smaller than the dimensions of the first recess structures A1 in the light-extraction structures 121 illustrated in FIGS. 14 to 16. In some embodiments, considering the process precision, the range of the dimension D1 of the first recess structure A1 in the light-extraction structure 121 illustrated in FIG. 9 is from 3 micrometers to 6 micrometers, and by setting the dimension D1 of the first recess structure A1 to be in the above range, the first sub-recess structure B1 can be made.

In some embodiments, the dimension D2 of the first sub-recess structure B1 in the direction parallel to the substrate 11 is greater than or equal to 2 micrometers. Considering the process precision, by making the dimension D2 of the first sub-recess structure B1 within this range, the formed first sub-recess structure B1 effectively increases the area proportion of the sidewall in the light-extraction structure 121, and the film layer of the light-emitting unit, which has a thinner thickness at the position of the sidewall, is used as the main light-emitting region, thereby increasing the effective light-emitting area of the display panel.

In some embodiments, the display panel further includes a drive structure layer, a color filter layer, a passivation layer, a planarization layer, and a pixel-defining layer. Referring to FIG. 18, which is a schematic cross-sectional structural diagram of another display panel according to some embodiments of the present disclosure, the display panel 10 includes: a substrate 11, a light-extraction structure layer 12, and a plurality of light-emitting units 13, wherein the light-emitting unit 13 includes a first electrode 131, a light-emitting layer 132, and a second electrode 133.

The display panel 10 further includes a drive structure layer 14. The drive structure layer 14 is disposed on the substrate 11 and electrically connected to the light-emitting unit 13, such that the light-emitting unit 13 is driven to emit light. In some embodiments, the plurality of film layers of the drive structure layer 14 include a first conductive structure layer 141, a first functional layer 142, a second conductive structure layer 143, a second functional layer 144, a third conductive structure 145, and a fourth conductive structure 146 disposed sequentially along a direction away from the substrate 10.

Illustratively, in some embodiments, the drive structure layer 14 includes a plurality of thin film transistors (TFTs) 147, wherein the first conductive structure layer 141 is a gate of the thin film transistor 147, the second conductive structure layer 143 is an active layer of the thin film transistor 147, the third conductive structure 145 is a source of the thin film transistor 147, and the fourth conductive structure 146 is a drain of the thin film transistor 147, the third conductive structure 145 and the fourth conductive structure 146 being in the same layer. In some embodiments, the materials of the first conductive structure layer 141, the third conductive structure 145, and the fourth conductive structure 146 include metallic materials such as copper, aluminum, and silver, and the material of the second conductive structure layer 143 includes semiconductor material such as amorphous silicon. In some embodiments, the first functional layer 142 is an insulating layer between the gate and the active layer, and the material of the first functional layer 142 includes silicon oxide, and/or, silicon nitride. In some embodiments, the second functional layer 144 is an ohmic contact layer between the active layer and the source and between the active layer and the drain.

The passivation layer 15 is disposed on a side, away from the substrate 11, of the drive structure layer 14, and the passivation layer 15 covers a plurality of thin film transistors 147 in the drive structure layer 14, thereby achieving the function of insulating protection and preventing external water vapor from corroding the drive structure layer 14. The passivation layer 15 is provided with a plurality of vias, and a plurality of vias are also defined in the light-extraction structure layer 12, such that the thin film transistor 147 is electrically connected to the light-emitting unit 13. Illustratively, the material of the passivation layer 15 includes silicon oxide, and/or, silicon nitride.

The color filter layer 16 is disposed on a side, away from the substrate 11, of the passivation layer 15, and an orthographic projection of the color filter layer 16 on the substrate 11 is overlapped with an orthographic projection of the light-emitting unit 13 on the substrate 11. In some embodiments, the color filter layer 16 includes a plurality of filter units 161, and the color filter layer 16 is configured to filter the light emitted by the light-emitting unit 13, so as to enhance the purity of the color of the light.

The pixel-defining layer 17 is disposed on a side, away from the substrate 11, of the light-extraction structure layer 12, a plurality of openings are defined in the pixel-defining layer 17, and the light-emitting units 13 are disposed in the plurality of openings of the pixel-defining layer 17, such that the pixel defining layer 17 is configured to define the plurality of light-emitting units 13.

In addition, in some embodiments, the thickness of the light-extraction structure layer 12 in a direction perpendicular to the substrate 11 ranges from 3 microns to 4 microns. In some embodiments, the minimum spacing between the light-extraction structure 121 and the color filter layer 16 is greater than 0.5 microns, and then the color filter layer 16 is not too close to the light-extraction structure 121, such that the color filter layer 16 can be avoided from affecting the shape of the light-extraction structure 121 as well as the light-extraction effect.

In summary, the embodiments of the present disclosure provide a display panel including a substrate, a light-extraction structure layer, and a plurality of light-emitting units. The light-extraction structure layer includes a plurality of light-extraction structures, wherein the light-extraction structure is provided with a plurality of first recess structures recessed in a direction towards the substrate on a side, away from the substrate, of the light-extraction structure, the first recess structure being provided with one or more first sub-recess structures recessed in the direction towards the substrate on a side, away from the substrate, of the first recess structure. Moreover, the light-emitting unit has a structure with a shape similar to the shape of the light-extraction structure. In this way, the light-emitting area of the light-emitting unit can be increased, and thus the brightness of the display panel can be enhanced.

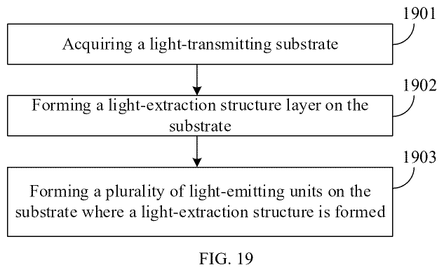

According to another aspect, the embodiments of the present disclosure provide a method for manufacturing a display panel. Referring to FIG. 19, which is a flowchart of the method for manufacturing a display panel according to the embodiments of the present disclosure, the method includes the following processes.

In process 1901, a substrate is acquired.

In process 1902, a light-extraction structure layer is formed on the substrate.

The light-extraction structure layer includes a plurality of light-extraction structures. The light-extraction structures are disposed on the substrate, and each of the plurality of light-extraction structures is provided with a plurality of first recess structures recessed in the direction towards the substrate on the side, away from the substrate, of the light-extraction structure. Each of the plurality of first recess structures is provided with one or more first sub-recess structures recessed in the direction towards the substrate on the side, away from the substrate, of the first recess structure.

In process 1903, a plurality of light-emitting units are formed on the substrate where the plurality of light-extraction structures are formed.

The plurality of light-emitting units respectively correspond to the plurality of light-extraction structures, each of the plurality of light-emitting units covers the corresponding light-extraction structure, the light-emitting unit is configured to emit light beams in a direction towards the substrate, and the light-emitting unit is provided with a second recess structure corresponding to the first recess structure and a second sub-recess structure corresponding to the first sub-recess structure, wherein the second recess structure has a recessed direction the same as the recessed direction of the first recess structure, an orthographic projection of the second recess structure is overlapped with an orthographic projection of the corresponding first recess structure on the substrate, the second sub-recess structure has a recessed direction the same as the recessed direction of the first sub-recess structure, and an orthographic projection of the second sub-recess structure on the substrate is overlapped with an orthographic projection of the corresponding first sub-recess structure on the substrate.

In summary, a display panel including a substrate, a light-extraction structure layer, and a plurality of light-emitting units is provided by the embodiments of the present disclosure. The light-extraction structure layer includes a plurality of light-extraction structures, wherein each of the plurality of light-extraction structures is provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure. Moreover, the light-emitting unit has a structure with a shape similar to the shape of the light-extraction structure. In this way, the light-emitting area of the light-emitting unit can be increased, and thus the brightness of the display panel can be enhanced.

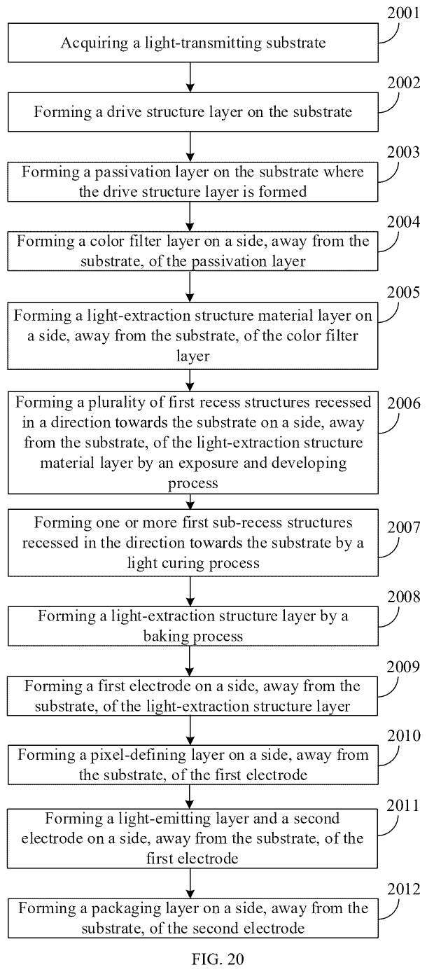

Embodiments of the present disclosure provide another method for manufacturing a display panel. Referring to FIG. 20, which is a flowchart of another method for manufacturing a display panel according to the embodiments of the present disclosure, the method includes the following processes.

In process 2001, a substrate is acquired.

In some embodiments, the substrate is configured to carry other film layers in the display panel to improve the flatness of the other film layers, and the material of the substrate includes a variety of light-transmitting materials such as glass.

In process 2002, a drive structure layer is formed on the substrate.

In some embodiments, the drive structure layer is formed on the substrate, and the drive structure layer includes a first conductive structure layer, a first insulating layer, a second conductive structure layer, a second insulating layer, a third conductive structure layer, and a fourth conductive structure layer disposed sequentially along a direction away from the substrate. In some embodiments, the drive structure layer includes a plurality of thin film transistors.

In process 2003, a passivation layer is formed on the substrate where the drive structure layer is formed.

In some embodiments, the passivation layer is formed on a side, away from the substrate, of the drive structure layer, and the passivation layer covers the plurality of thin film transistors in the drive structure layer, to achieve the function of insulating protection to prevent external water vapor from corroding the drive structure layer. In some embodiments, a plurality of vias for electrically connecting the thin film transistors to the light-emitting units are defined in the passivation layer. Illustratively, the material of the passivation layer includes silicon oxide, and/or, silicon nitride.

In process 2004, a color filter layer is formed on the side, away from the substrate, of the passivation layer.

In some embodiments, the color filter layer is formed on a side, away from the substrate, of the passivation layer, and an orthographic projection of the color filter layer on the substrate is overlapped with an orthographic projection of the light-emitting unit on the substrate. The color filter layer includes a plurality of filter units, and the color filter layer filters the light emitted by the light-emitting unit, so as to improve the purity of the color of the light.

In process 2005, a light-extraction structure material layer is formed on a side, away from the substrate, of the color filter layer.

In some embodiments, the light-extraction structure material layer is formed on a side, away from the substrate, of the color filter layer. The light-extraction structure material layer is configured to form a plurality of light-extraction structures including a first recess structure and a first sub-recess structure. The material of the light-extraction structure material layer includes a resin material, and illustratively, the material of the light-extraction structure material layer is a negative resin material.

In process 2006, a plurality of first recess structures recessed in a direction towards the substrate are formed on a side, away from the substrate, of the light-extraction structure material layer by an exposure and developing process.

In some embodiments, the first recess structure is formed by an exposure and developing process. In some embodiments, because the material of the light-extraction structure material layer is a negative resin material, a pattern to be imaged is projected onto the light-extraction structure material layer by irradiation of a light source during the exposure process, wherein the irradiated region undergoes a chemical reaction and the unirradiated region does not undergo a chemical reaction. In the developing process, the developer solution dissolves the light-extraction structure material layer in the region not irradiated by the light, such that a plurality of first recess structures recessed in the direction towards the substrate are formed on the side, away from the substrate, of the light-extraction structure material layer.

In process 2007, one or more first sub-recess structures recessed in the direction towards the substrate are formed by a light curing process.

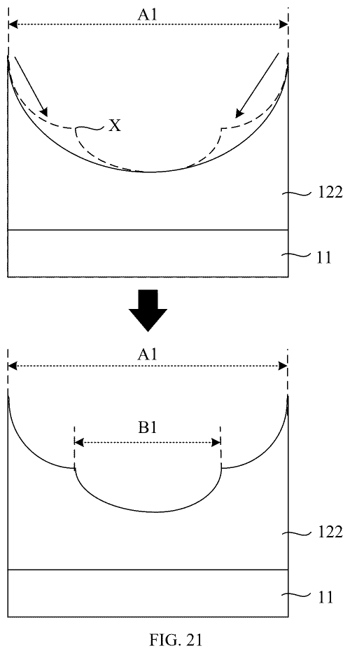

In some embodiments, the first sub-recess structure is formed by a light curing process. Referring to FIG. 21, FIG. 21 being a schematic diagram of a preparation process of a first sub-recess structure according to the present disclosure, upon forming the first sub-recess structure A1 by the exposure and developing process, the material of the light-extraction structure material layer 122 is not completely transformed into a solid state, and still has a certain fluidity. Specifically, the material in the light-extraction structure material layer 122 disposed on the side far away from the substrate 11 tends to flow in the direction towards the substrate 11, and in the case that the material of the light-extraction structure material layer 122 flows to and piles up at the target position X, the material of the light-extraction structure material layer 122 is cured by a light curing process, such that the first sub-recess structure B1 recessed in the direction towards the substrate is formed, wherein the target position X is a position where the first sub-recess structure B1 is farthest away from the substrate 11. Because the photochemical reaction of the material of the light-extraction structure material layer 122 occurs at a fast rate, the curing rate of the light curing process is high, which ensures higher accuracy and controllability for the position of the first sub-recess structure B1 to be formed.

In addition, in some embodiments, the time interval between the developing process and the light curing process is controlled to adjust the position of the first sub-recess structure B1 and the size of the first sub-recess structure B1 in a direction perpendicular to the substrate 11. The longer the time interval between the developing process and the light curing process is, the closer the position in the first sub-recess structure B1 that is farthest from the substrate 11 is to the substrate 11, and the smaller the size of the first sub-recess structure B1 is in the direction parallel to the substrate 11. The shorter the time interval between the developing process and the light curing process, the further the position in the first sub-recess structure B1 farthest from the substrate 11 is from the substrate 11, and the larger the size of the first sub-recess structure B1 is in the direction parallel to the substrate 11.

In process 2008, a light-extraction structure layer is formed by a baking process.

In some embodiments, the solvent in the light-extraction structure material layer is removed by the baking process, such that the formed light-extraction structure layer can be made to have good mechanical properties and stability.

In process 2009, a first electrode is formed on the side, away from the substrate, of the light-extraction structure layer.

In some embodiments, the first electrode is formed on a side, away from the substrate, of the light-extraction structure layer. The first electrode is provided with a second recess structure corresponding to the first recess structure, and a second sub-recess structure corresponding to the first sub-recess structure, so as to increase the light-emitting area of the light-emitting layer, which in turn increases the brightness of the display panel. In some embodiments, the first electrode is an anode, and the first electrode is electrically connected to the drive structure layer. Illustratively, the material of the first electrode includes indium tin oxide.

In process 2010, a pixel-defining layer is formed on a side, away from the substrate, of the first electrode.

In some embodiments, the pixel-defining layer is formed on a side, away from the substrate, of the first electrode, a plurality of openings are defined in the pixel-defining layer, and the light-emitting units are disposed in the plurality of openings of the pixel-defining layer, such that the pixel defining layer is configured to define the plurality of light-emitting units.

In process 2011, a light-emitting layer and a second electrode are formed on a side, away from the substrate, of the first electrode.

In some embodiments, the light-emitting layer is formed on a side, away from the substrate, of the first electrode, and the second electrode is formed on a side, away from the substrate, of the light-emitting layer. Both the light-emitting layer and the second electrode are provided with a second recess structure corresponding to the first recess structure, and a second sub-recess structure corresponding to the first sub-recess structure, such that the light-emitting area of the light-emitting layer is increased, which in turn increases the brightness of the display panel. In some embodiments, the light-emitting layer is an organic light-emitting layer, and the second electrode is a cathode. The first electrode in cooperation with the second electrode is configured to drive the light-emitting layer. Illustratively, the manufacturing processes of the first electrode, the light-emitting layer, and the second electrode include evaporation processes.

In process 2012, a packaging layer is formed on a side, away from the substrate, of the second electrode.

In some embodiments, the packaging layer is formed on a side, away from the substrate, of the second electrode, and the packaging layer is configured to protect the display panel and to avoid erosion of outside water and oxygen. The packaging layer is a single-layer or multi-layer structure. In some embodiments, the packaging layer includes an inorganic packaging layer, and/or, an organic packaging layer.

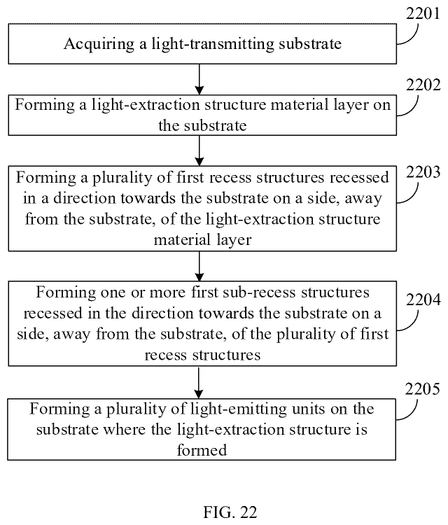

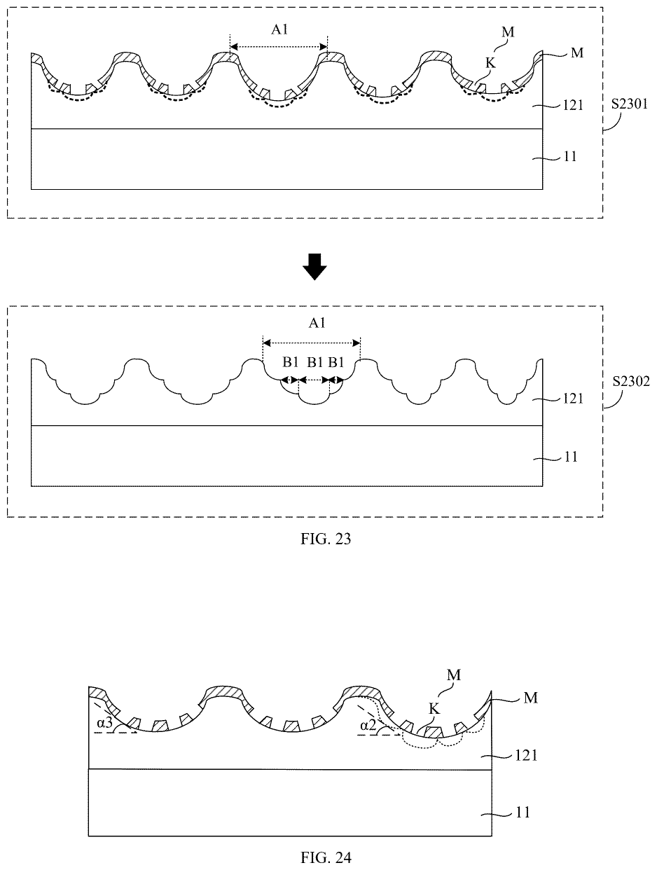

Embodiments of the present disclosure provide another method for manufacturing a display panel. Referring to FIG. 22, which is a flowchart of another method for manufacturing a display panel according to the embodiments of the present disclosure, the method includes the following processes.

In process 2201, a substrate is acquired.

The substrate is configured to carry other film layers in the display panel to improve the flatness of the other film layers, and the material of the substrate includes a variety of light-transmitting materials such as glass.

In process 2202, a light-extraction structure material layer is formed on the substrate.

In some embodiments, the light-extraction structure material layer is formed on the substrate. The light-extraction structure material layer is configured to form a plurality of light-extraction structures including a first recess structure and a first sub-recess structure. The material of the light-extraction structure material layer includes a resin material. In some embodiments, the material of the light-extraction structure material layer includes a negative photoresist.

In process 2203, a plurality of first recess structures recessed in a direction towards the substrate are formed on a side, away from the substrate, of the light-extraction structure material layer.

In some embodiments, the first recess structure is formed on a side, away from the substrate, of the light-extraction structure material layer. The manufacturing process of the first recess structure includes exposure, developing, baking, etc.

In process 2204, one or more first sub-recess structures recessed in the direction towards the substrate are formed on a side, away from the substrate, of the plurality of first recess structures.

In some embodiments, the first sub-recess structure is formed on a side, away from the substrate, of the plurality of first recess structures. Specifically, referring to FIG. 23, which is a schematic diagram of a preparation process of another first sub-recess structure according to the present disclosure (in some embodiments, FIG. 23 is a schematic diagram of a preparation process of the first sub-recess structure in the light-extraction structure illustrated in FIG. 15). The preparation process of the first sub-recess structure includes the following processes.

In process S2301, a hard mask M is formed on a surface at aside, away from the substrate 11, of the first recess structure A1, the hard mask M being provided with a plurality of hard mask openings K.

In process S2302, the first sub-recess structure B1 is formed by etching the light-extraction structure material layer 122 disposed in the hard mask opening and then removing the hard mask M.

In some embodiments, the material of the hard mask M is metallic. The manufacturing process of the hard mask M is a patterning process, and the patterning process involved in the embodiments of the present disclosure includes coating a photoresist, exposure, developing, etching, stripping the photoresist, etc. In addition, the number of hard mask openings K is the same as the number of first sub-recess structures B1 formed. Illustratively, the first recess structures A1 illustrated in FIG. 9, FIG. 12, and FIG. 13 include one first sub-recess structure B1, and thus the corresponding number of hard mask openings K is one. The first recess structure A1 illustrated in FIG. 14 includes two first sub-recess structures B1, and thus the number of corresponding hard mask openings K is two. FIG. 15 illustrates the first recess structure A1 including three first sub-recess structures B1, and thus the number of corresponding hard mask openings K is three. The first recess structure A1 illustrated in FIG. 16 includes four first sub-recess structures B1, and thus the number of corresponding hard mask openings K is four.

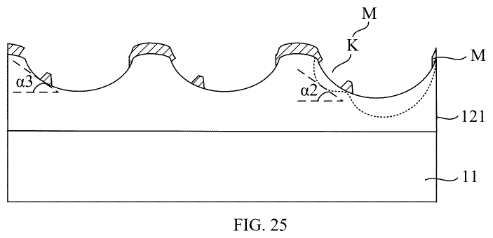

Furthermore, referring to FIGS. 24 and 25, FIG. 24 being a schematic diagram of a cross-sectional structure of a hard mask according to the present disclosure (in some embodiments, FIG. 24 is a schematic cross-sectional structural diagram of a hard mask corresponding to the light-extraction structure illustrated in FIG. 14), and FIG. 25 being a schematic cross-sectional structural diagram of another hard mask provided by the present disclosure (in some embodiments, FIG. 25 is a schematic cross-sectional structural diagram of a hard mask corresponding to the light-extraction structure illustrated in FIG. 16), in the light-extraction structure illustrated in FIG. 14 and FIG. 16, the ratio of the orthographic projection of the first sub-recess structure on the substrate to the orthographic projection of the first recess structure on the substrate is close to 1. Therefore, in order to make a slope angle α2 of the second sidewall of the ultimately formed first sub-recess structure in the range of 30 degrees to 45 degrees, the slope angle α3 of the first sidewall of the first recess structure formed in process 1903 is made to be less than 30 degrees, to facilitate preparing the first recess structure as well as the first sub-recess structure satisfying the range of slope angle.

In process 2205, a plurality of light-emitting units are formed on the substrate where the light-extraction structure is formed.

The plurality of light-emitting units respectively correspond to the plurality of light-extraction structures, the light-emitting unit covers the corresponding light-extraction structure, the light-emitting unit is configured to emit light beams in a direction towards the substrate, and the light-emitting unit is provided with a second recess structure corresponding to the first recess structure and a second sub-recess structure corresponding to the first sub-recess structure. The second recess structure has a recessed direction same as the recessed direction of the first recess structure, an orthographic projection of the second recess structure on the substrate is overlapped with an orthographic projection of the corresponding first recess structure on the substrate, the second sub-recess structure has a recessed direction same as the recessed direction of the first sub-recess structure, and an orthographic projection of the second sub-recess structure on the substrate is overlapped with an orthographic projection of the corresponding first sub-recess structure on the substrate.

In summary, the embodiments of the present disclosure provide a method for manufacturing a display panel including a substrate, a light-extraction structure layer, and a plurality of light-emitting units. Therein, the light-extraction structure is provided with a plurality of first recess structures recessed in a direction towards the substrate on a side, away from the substrate, of the light-extraction structure, the first recess structure being provided with one or more first sub-recess structures recessed in the direction towards the substrate on a side, away from the substrate, of the first recess structure. Moreover, the light-emitting unit has a structure with a shape similar to the shape of the light-extraction structure. In this way, the light-emitting area of the light-emitting unit is increased, and thus the brightness of the display panel is enhanced.

According to another aspect, the embodiments of the present disclosure provide a display device. The display device includes a power assembly and a display panel provided in the above embodiments. The power assembly is configured to supply power to the display panel. The display device includes a variety of devices with a display function. Illustratively, in some embodiments, the display device is an OLED display device.

Because the display device includes the display panel provided in the above embodiments, in turn, the display device can achieve a similar effect, i.e., the brightness of the display device can be improved.

In summary, the embodiments of the present disclosure provide a display device including a substrate, a light-extraction structure layer, and a plurality of light-emitting units. Therein, the light-extraction structure is provided with a plurality of first recess structures recessed in a direction towards the substrate on a side, away from the substrate, of the light-extraction structure, the first recess structure being provided with one or more first sub-recess structures recessed in the direction towards the substrate on a side, away from the substrate, of the first recess structure. Moreover, the light-emitting unit has a structure with a shape similar to the shape of the light-extraction structure. In this way, the light-emitting area of the light-emitting unit is increased, and thus the brightness of the display panel is enhanced.

The term “and/or” in the present disclosure is merely a description of an association relationship of the associated objects, indicating that three kinds of relationships may exist, e.g., the phrase “A and/or B” means (A), (B), or (A and B). In addition, the symbol “/” in the disclosure generally indicates that the associated contextual objects are in an “or” relationship.

It is noted that in the accompanying drawings, the dimensions of the layers and regions may be exaggerated for the sake of clarity of the illustrations. Moreover, it is understood that in the case that an element or a layer is referred to as being “on” another element or layer, the element or the layer is directly on the other element or there are intervening layers. Further, it can be understood that in the case that an element or a layer is referred to as being “under” another element or layer, it is directly under the other element, or there are one or more intermediate layers or elements. It is also understood that in the case that a layer or element is referred to as being “between” two layers or elements, the layer or element is the only layer between the two layers or elements, or there is more than one intermediate layer or element. Similar reference signs throughout the description indicate similar elements.

In the present disclosure, the terms “first,” “second,” “third,” and “fourth” are used only for descriptive purposes and are not to be understood as indicating or implying relative importance. The term “plurality” refers to two or more, unless otherwise expressly limited.

Described are merely some exemplary embodiments of the present disclosure, which are not intended to limit the present disclosure, and any modifications, equivalent substitutions, improvements, and the like made within the concepts and principles of the present disclosure shall be included in the scope of protection of the present disclosure.

1. A display panel, comprising:
a substrate;
a light-extraction structure layer, wherein the light-extraction structure layer comprises a plurality of light-extraction structures, each of the plurality of light-extraction structures being disposed on the substrate and provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure; and
a plurality of light-emitting units, wherein the plurality of light-emitting units are disposed on the substrate having the light-extraction structure layer and respectively correspond to the plurality of light-extraction structures, each of the plurality of light-emitting units covers the light-extraction structure corresponding to the light-emitting unit, and the light-emitting unit is provided with a second recess structure corresponding to the first recess structure and a second sub-recess structure corresponding to the first sub-recess structure, wherein the second recess structure has a recessed direction the same as a recessed direction of the first recess structure, an orthographic projection of the second recess structure on the substrate is overlapped with an orthographic projection of the corresponding first recess structure on the substrate, the second sub-recess structure has a recessed direction the same as a recessed direction of the first sub-recess structure, and an orthographic projection of the second sub-recess structure on the substrate is overlapped with an orthographic projection of the corresponding first sub-recess structure on the substrate.

2. The display panel according to claim 1, wherein the plurality of light-emitting units comprise light-emitting units of at least three colors; wherein
light-emitting units of at least two different colors in the light-emitting units of at least three colors correspond to different target ratios of the first sub-recess structure in the light-extraction structure, each of the target ratios being a ratio of the orthographic projection of the first sub-recess structure on the substrate to an orthographic projection of the light-extraction structure on the substrate.

3. The display panel according to claim 2, wherein in the light-emitting units of at least three colors, the light-emitting units of different colors correspond to the different target ratios of the first sub-recess structure in the light-extraction structure.

4. The display panel according to claim 2, wherein each of the target ratios of the first sub-recess structure in the light-extraction structure is negatively correlated with a lifetime of the light-emitting unit corresponding to the light-extraction structure.

5. The display panel according to claim 1, wherein the first recess structure comprises a first bottom and a first sidewall on a side, away from the substrate, of the first bottom, the first sidewall having a slope angle ranging from 30 degrees to 45 degrees.

6. The display panel according to claim 5, wherein the light-emitting unit comprises a first portion disposed on the first bottom and a second portion disposed on the first sidewall, the first portion having a thickness greater than a thickness of the second portion.

7. The display panel according to claim 5, wherein the first sub-recess structure comprises a second bottom and a second sidewall on a side, away from the substrate, of the second bottom, the second sidewall having a slope angle ranging from 30 degrees to 45 degrees.

8. The display panel according to claim 1, wherein each of the plurality of first recess structures is provided with one first sub-recess structure, a geometric center of the first sub-recess structure being on a centerline of the first recess structure.

9. The display panel according to claim 1, wherein each of the plurality of first recess structures is provided with one first sub-recess structure, a geometric center of the first sub-recess structure being outside a centerline of the first recess structure.

10. The display panel according to claim 1, wherein each of the plurality of first recess structures is provided with two first sub-recess structures of different sizes, the two first sub-recess structures being connected.

11. The display panel according to claim 1, wherein each of the plurality of first recess structures is provided with a plurality of first sub-recess structures, the plurality of first sub-recess structures comprising a central sub-recess structure and a plurality of peripheral sub-recess structures surrounding the central sub-recess structure.

12. The display panel according to claim 1, wherein each of the plurality of first recess structures is provided with a plurality of first sub-recess structures, the plurality of first sub-recess structures being arranged around a centerline of the first recess structure.

13. The display panel according to claim 1, wherein a plurality of sub-regions are arranged on a side, away from the substrate, of the first recess structure, each of the plurality of sub-regions being a region with a slope angle monotonic in a direction perpendicular to the substrate, and the plurality of sub-regions satisfying:
$${\sum }_{i = 1}^{k} ( {d}_{i} / tan {θ}_{i} ) = D 1 ;$$
wherein k represents a number of the plurality of sub-regions, d represents a dimension of the sub-region in the direction perpendicular to the substrate, θ represents an angle between a line connecting two endpoints on the sub-region and the substrate, the two endpoints being respectively a point in the sub-region furthest from the substrate and a point in the sub-region closest to the substrate, and D1 represents a dimension of the first recess structure in a direction parallel to the substrate.

14. The display panel according to claim 11, wherein the angle θ between the line connecting the two endpoints on the sub-region and the substrate ranges from 30 degrees to 45 degrees.

15. The display panel according to claim 1, wherein the first recess structure and the first sub-recess structure each comprise a curved recess structure or a trapezoidal recess structure, the trapezoidal recess structure having a trapezoidal section in a direction perpendicular to the substrate.

16. The display panel according to claim 1, wherein the first recess structure has a dimension ranging from 3 microns to 10 microns in a direction parallel to the substrate.

17. The display panel according to claim 1, wherein the first sub-recess structure has a dimension greater than or equal to 2 microns in a direction parallel to the substrate.

18. A method for manufacturing a display panel, comprising:
acquiring a substrate;
forming a light-extraction structure layer on the substrate, wherein the light-extraction structure layer comprises a plurality of light-extraction structures, the plurality of light-extraction structures being disposed on the substrate, and each of the plurality of light-extraction structures being provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure; and
forming a plurality of light-emitting units on the substrate where the plurality of light-extraction structures are formed, wherein the plurality of light-emitting units respectively correspond to the plurality of light-extraction structures, each of the plurality of light-emitting units covers the light-extraction structure corresponding to the light-emitting unit, the light-emitting unit is configured to emit light beams in a direction towards the substrate, and the light-emitting unit is provided with a second recess structure corresponding to the first recess structure and a second sub-recess structure corresponding to the first sub-recess structure, wherein the second recess structure has a recessed direction the same as a recessed direction of the first recess structure, an orthographic projection of the second recess structure on the substrate is overlapped with an orthographic projection of the first recess structure on the substrate, the second sub-recess structure has a recessed direction the same as a recessed direction of the first sub-recess structure, and an orthographic projection of the second sub-recess structure on the substrate is overlapped with an orthographic projection of the first sub-recess structure on the substrate.

19. The method according to claim 18, wherein forming the light-extraction structure layer on the substrate comprises:
forming a light-extraction structure material layer on the substrate;
forming the plurality of first recess structures recessed in the direction towards the substrate on a side, away from the substrate, of the light-extraction structure material layer by an exposure and developing process;
forming the one or more first sub-recess structures recessed in the direction towards the substrate by a light curing process; and
forming the light-extraction structure layer by a baking process.

20. A display device, comprising a power assembly and a display panel, wherein the display panel comprises:
a substrate;
a light-extraction structure layer, wherein the light-extraction structure layer comprises a plurality of light-extraction structures, each of the plurality of light-extraction structures being disposed on the substrate and provided with a plurality of first recess structures recessed in a direction towards the substrate on a side, away from the substrate, of the light-extraction structure, each of the plurality of first recess structures being provided with one or more first sub-recess structures recessed in the direction towards the substrate on a side, away from the substrate, of the first recess structure; and
a plurality of light-emitting units, wherein the plurality of light-emitting units are disposed on the substrate having the light-extraction structure layer and respectively correspond to the plurality of light-extraction structures, each of the plurality of light-emitting units covers the light-extraction structure corresponding to the light-emitting unit, and the light-emitting unit is provided with a second recess structure corresponding to the first recess structure and a second sub-recess structure corresponding to the first sub-recess structure, wherein the second recess structure has a recessed direction the same as a recessed direction of the first recess structure, an orthographic projection of the second recess structure on the substrate is overlapped with an orthographic projection of the corresponding first recess structure on the substrate, the second sub-recess structure has a recessed direction the same as a recessed direction of the first sub-recess structure, and an orthographic projection of the second sub-recess structure on the substrate is overlapped with an orthographic projection of the corresponding first sub-recess structure on the substrate.
